(19) United States
(12) Patent Application Publication
(10) Pub. No.: US 2025/0130129 A1
(43) Pub. Date: Apr. 24, 2025

(54) PRESSURE SENSOR HAVING IMPROVED REJECTION OF UNDESIRED STIMULI

(71) Applicant: STMicroelectronics International N.V., Geneva (CH)

(72) Inventors: Filippo DANIELE, Milano (IT); Enri DUQI, Milan (IT); Lorenzo BALDO, Bareggio (IT)

(73) Assignee: STMicroelectronics International N.V., Geneva (CH)

(21) Appl. No.: 18/915,158

(22) Filed: Oct. 14, 2024

(30) Foreign Application Priority Data
Oct. 24, 2023 (IT) 102023000022215

(51) Int. Cl. G01L 19/04; G01L 9/00; G01L 13/02

(52) U.S. Cl. CPC G01L 19/04; G01L 9/0052; G01L 13/025

(57) ABSTRACT

A pressure sensor has a body having a first chamber and a second chamber hermetically separated from the first chamber; a first detection structure which is arranged in the first chamber, has a first deformable element and a first buried cavity within the first detection structure, wherein the first deformable element is configured to undergo a deformation as a function of a pressure difference between the first chamber and the first buried cavity. The sensor also has a second detection structure which is arranged in the second chamber, has a second deformable element and a second buried cavity within the second detection structure, wherein the second deformable element is configured to undergo a deformation as a function of a pressure difference between the second chamber and the second buried cavity. The sensor also has a first channel that extends into the body and is configured to fluidically couple the first buried cavity with the second chamber; and a second channel that extends into the body and is configured to fluidically couple the second buried cavity to the first chamber.

### BACKGROUND

### Technical Field

The present disclosure relates to a pressure sensor, in particular of MEMS (“Micro Electro-Mechanical System”) type, having improved rejection of undesired stimuli.

### Description of the Related Art

MEMS pressure sensors are known having a membrane configured to deform as a function of an external pressure to be measured. By detecting the deformation of the membrane, for example through piezoresistors, a measurement of the external pressure may be obtained.

However, as known, MEMS pressure sensors are subject to undesired mechanical stimuli that may cause a spurious, undesired deformation of the membrane. This causes low detection accuracy of MEMS pressure sensors.

Undesired mechanical stimuli may be divided into external stimuli, for example bending of the PCB having the pressure sensor mounted thereon, thermal expansion of the pressure sensor package, humidity, etc.; and internal stimuli, for example thermal expansion of the materials that form the pressure sensor and hysteresis of the residual mechanical stress following temperature variations.

According to one approach, the membrane is formed into a structure suspended with respect to the body of the pressure sensor. This allows the membrane to be decoupled from external mechanical stimuli. However, in this approach, the membrane remains sensitive to internal mechanical stimuli.

According to a different approach, a MEMS pressure sensor comprises a further membrane which is configured not to deform as a function of the external pressure. The further membrane may be used as a reference to cancel the deformation contribution caused by internal mechanical stimuli. However, the fact that the further membrane does not deform as a function of the pressure to be measured causes the pressure sensor to have low sensitivity and high area occupation.

### BRIEF SUMMARY

According to the present disclosure, a pressure sensor is therefore provided. The pressure sensor has a body having a first chamber and a second chamber hermetically separated from the first chamber; a first detection structure which is arranged in the first chamber, has a first deformable element and a first buried cavity within the first detection structure, wherein the first deformable element is configured to undergo a deformation as a function of a pressure difference between the first chamber and the first buried cavity. The sensor also has a second detection structure which is arranged in the second chamber, has a second deformable element and a second buried cavity within the second detection structure, wherein the second deformable element is configured to undergo a deformation as a function of a pressure difference between the second chamber and the second buried cavity. The sensor also has a first channel that extends into the body and is configured to fluidically couple the first buried cavity with the second chamber; and a second channel that extends into the body and is configured to fluidically couple the second buried cavity to the first chamber.

### BRIEF DESCRIPTION OF THE SEVERAL VIEWS OF THE DRAWINGS

For a better understanding of the present disclosure, embodiments thereof are now described, purely by way of non-limiting example, with reference to the attached drawings, wherein:

FIG. 1 shows a top-plan view of a MEMS pressure sensor, according to one embodiment;

FIG. 2 shows a cross-section of the MEMS pressure sensor of FIG. 1, along a section line II-II of FIG. 1;

FIG. 3 shows a cross-section of a portion of the MEMS pressure sensor of FIG. 1, along a section line III-III of FIG. 1;

FIG. 4 shows a cross-section of a different portion of the MEMS pressure sensor of FIG. 1, along a section line IV-IV of FIG. 1;

FIG. 5 shows a circuit diagram of a detection circuit coupeable to the MEMS pressure sensor of FIG. 1;

FIG. 6 shows a simplified view of a portion of the MEMS pressure sensor of FIG. 1, in use;

FIG. 7 shows a cross-section of a MEMS pressure sensor, according to a different embodiment; and

FIG. 8 shows a circuit diagram of a detection circuit coupeable to a MEMS pressure sensor, according to one embodiment.

### DETAILED DESCRIPTION

The following description refers to the arrangement shown in the attached Figures; consequently, expressions such as “above,” “below,” “lower,” “upper,” “right,” “left,” “top,” “bottom,” and the like, relate to the attached Figures and should not be interpreted in a limiting manner.

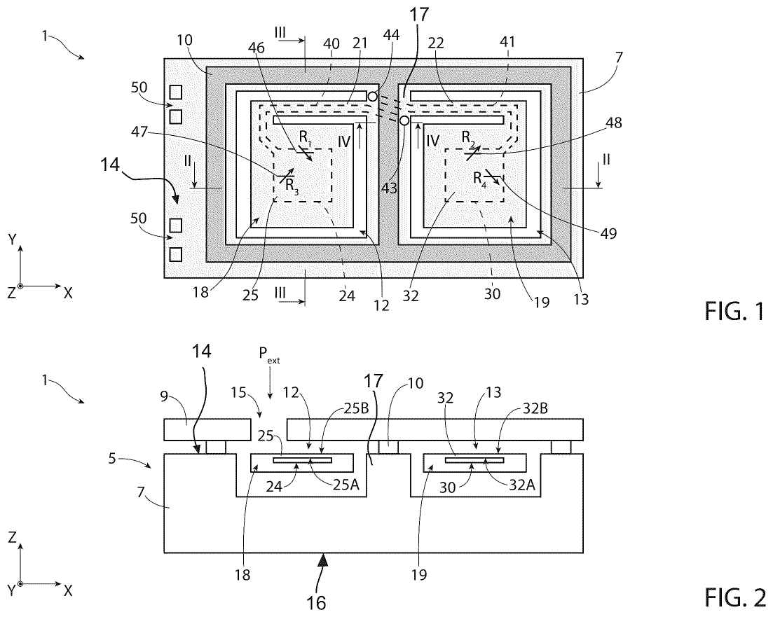

FIGS. 1 and 2 show a pressure sensor 1, hereinafter also simply referred to as sensor 1, in a Cartesian reference system XYZ having a first axis X, a second axis Y and a third axis Z.

The sensor 1 is of MEMS type.

The sensor 1 may be manufactured through micro-and nano-machining techniques known per se, for example starting from a wafer of semiconductor material, in particular silicon, and subsequent processing steps, for example including lithography, chemical etching, growth, annealing, dicing, bonding, etc., typical of the semiconductor industry.

The sensor 1 is configured to detect an external pressure Pₑₓₜ.

The sensor 1 is formed in a body 5 comprising a lower substrate 7 and an upper substrate 9 mutually bonded through a bonding region 10.

The lower substrate 7 and the upper substrate 9 are of semiconductor material, in particular silicon. However, the lower substrate 7 and the upper substrate 9 may be of different material or comprise portions or layers of different material, for example insulating material, depending on the specific manufacturing processes used.

The bonding region 10 is of a material that allows a hermetic bonding to be obtained between the lower substrate 7 and the upper substrate 9. For example, the bonding region 10 may be of aluminum-germanium (Al—Ge). Bonding through Al—Ge may allow very low pressures to be obtained, for example even lower than 20 mbar.

FIG. 1 shows, for clarity, the sensor 1 without the upper substrate 9.

The sensor 1 comprises a first chamber 12 and a second chamber 13 arranged in the body 5. The first chamber 12 and the second chamber 13 extend into a first surface 14 of the lower substrate 7 of the body 5 and terminate within the lower substrate 7 of the body 5 before reaching a second surface 16 of the lower substrate 7 of the body 5 opposite to the first surface 14. A wall portion 17 of the lower substrate 7 of the body is between the first chamber 12 ant the second chamber 13, and the wall portion 17 partially delimits the first chamber 12 and partially delimits the second chamber 13.

The first chamber 12 and the second chamber 13 are hermetically separated from each other by the bonding region 10.

In this embodiment, the body 5 comprises an opening 15 that couples the first chamber 12 with the outside of the sensor 1. In other words, the opening 15 causes the first chamber 12 to be at the external pressure Pₑₓₜ.

In the embodiment shown, the opening 15 extends through the upper substrate 9, throughout its thickness along the third axis Z.

The sensor 1 further comprises a first detection structure 18 arranged in the first chamber 12 and a second detection structure 19 arranged in the second chamber 13.

In detail, in this embodiment, the first and the second detection structures 18, 19 are structures suspended in the first and, respectively, in the second chamber 12, 13 through respective elastic elements 21, 22.

The first and the second detection structures 18, 19 and the elastic elements 21, 22 may be of semiconductor material, in particular silicon, formed starting from the same wafer used to form the lower substrate 7, through subsequent processing steps comprising lithography, growth, chemical etching, etc.

The elastic element 21 extends into the first chamber 12 between the first detection structure 18 and the lower substrate 7. The elastic element 22 extends into the second chamber 13 between the second detection structure 19 and the lower substrate 7.

The elastic elements 21, 22 are configured so as to mechanically decouple each the respective detection structure 18, 19 from the lower substrate 7. In this manner, the detection structures 18, 19 may be decoupled by external mechanical stimuli applied on the body 5.

Shape and dimensions of the elastic elements 21, 22 may be chosen, during the design step, based on the desired elastic properties of the elastic elements 21, 22.

The first detection structure 18 comprises a buried cavity 24 that extends within the first detection structure 18 and a membrane 25 that faces the buried cavity 24.

In detail, the membrane 25 has a lower surface 25A facing the buried cavity 24 and an upper surface 25B facing the first chamber 12.

In practice, the buried cavity 24 delimits the membrane 25 at the bottom and the first chamber 12 delimits the membrane 25 at the top.

Position of the buried cavity 24 within the first detection structure 18 and dimensions of the buried cavity 24 may be chosen, during the design step, depending on the desired dimensions of the membrane 25. For example, the membrane 25 may have a thickness, along the third axis Z, comprised for example between 2 μm and 20 μm, and an area, measured in an XY plane, comprised between 40×40 μm² and 600×600 μm².

The second detection structure 19 comprises a buried cavity 30 that extends within the second detection structure 19 and a membrane 32 that faces the buried cavity 30.

In detail, the membrane 32 has a lower surface 32A facing the buried cavity 30 and an upper surface 32B facing the second chamber 13.

In practice, the buried cavity 30 delimits the membrane 32 at the bottom and the second chamber 13 delimits the membrane 32 at the top.

Position of the buried cavity 30 within the second detection structure 19 and dimensions of the buried cavity 30 may be chosen, during the design step, depending on the desired dimensions of the membrane 32. For example, the membrane 32 may have a thickness, along the third axis Z, comprised for example between 2 μm and 20 μm, and an area, measured in the XY plane, comprised between 40×40 μm² and 600×600 μm².

In particular, the first and the second detection structures 18, 19 may be designed to be equal to each other. For example, the membranes 30, 32 may have the same dimensions as each other. This allows the detection accuracy of the sensor 1 to be improved.

The sensor 1 further comprises a channel 40 that extends into the body 5 between the buried cavity 24 and the second chamber 13 and a channel 41 that extends into the body 5 between the buried cavity 30 and the first chamber 12.

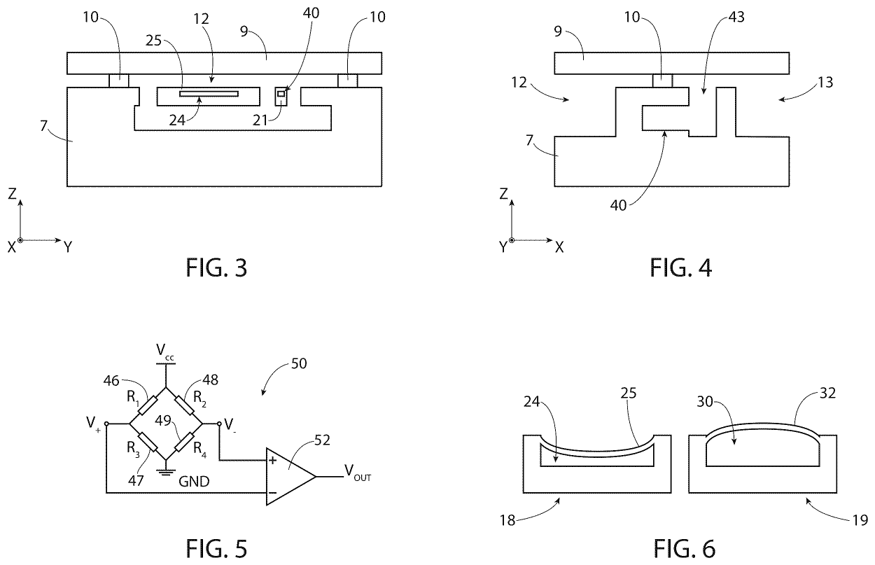

The channel 40, details of which are shown in FIGS. 3 and 4, is open at a first end on the buried cavity 24 and at a second end on the second chamber 13.

In practice, the channel 40 causes the buried cavity 24 and the second chamber 13 to be at a same pressure P₁.

The channel 41 is open at a first end on the buried cavity 30 and at a second end on the first chamber 12.

In practice, the channel 41 causes the buried cavity 30 and the first chamber 12 to be at a same pressure P₂, which here is equal to the external pressure Pext.

In detail, the channel 40 extends, starting from the buried cavity 24, buried within the first detection structure 18, the elastic element 21 and part of the lower substrate 7, towards the second chamber 13.

In this embodiment, the channel 40 comprises a via 43 that extends, along the third axis Z, from a surface of the lower substrate 7 which faces the second chamber 13 towards the inside of the lower substrate 7. In practice, the via 43 may fluidically couple the buried portion of the channel 40 with the second chamber 13.

In detail, the channel 41 extends, starting from the buried cavity 30, buried within the second detection structure 19, the elastic element 22 and part of the lower substrate 7, towards the first chamber 12.

In this embodiment, the channel 41 comprises a via 44 that extends, along the third axis Z, from a surface of the lower substrate 7 which faces the first chamber 12 towards the inside of the lower substrate 7. In practice, the via 44 may fluidically couple the buried portion of the channel 41 with the first chamber 12.

The buried cavities 24, 30 and the buried portions of the channels 40, 41 may be formed for example through formation and subsequent removal of sacrificial layers; or through subsequent steps comprising growth, lithography, chemical etching and annealing, as for example described in the European patent EP1577656.

The vias 43, 44 may be formed with the same chemical etching used to define the elastic elements 21, 22 and the detection structures 18, 19.

The sensor 1 further comprises one or more transduction elements, here two piezoresistors 46, 47, coupled to the first detection structure 18 and one or more transduction elements, here two piezoresistors 48, 49, coupled to the second detection structure 19.

The piezoresistors 46, 47 are configured to detect a deformation of the membrane 25.

In detail, the piezoresistors 46, 47 have a resistance R₁, R₃, respectively, which is variable as a function of the deformation of the membrane 25.

In particular, the resistances R₁, R₃ are sensitive both to the direction (upwards or downwards along the third axis Z) and to the extent of the deformation of the membrane 25.

In this embodiment, the piezoresistors 46, 47 are configured in such a way that the respective resistances R₁, R₃ undergo, in response to the deformation of the membrane 25, a variation having sign opposite to each other.

For example, in response to a downward deformation of the membrane 25, the piezoresistor 47 may be configured to undergo a positive variation (increase) of the respective resistance R₃ and the piezoresistor 46 may be configured to undergo a negative variation (decrease) of the respective resistance R₁.

The piezoresistors 48, 49 are configured to detect the deformation of the membrane 32.

In detail, the piezoresistors 48, 49 have a resistance R₂, R₄, respectively, which is variable as a function of the deformation of the membrane 32.

In particular, the resistances R₂, R₄ are sensitive both to the direction (upwards or downwards along the third axis Z) and to the extent of the deformation of the membrane 32.

In this embodiment, the piezoresistors 48, 49 are configured in such a way that the respective resistances R₂, R₄ undergo, in response to the deformation of the membrane 32, a variation having sign opposite to each other. For example, in response to an upward deformation of the membrane 32, the piezoresistor 48 may be configured to undergo a positive variation (increase) of the respective resistance R₂ and the piezoresistor 49 may be configured to undergo a negative variation (decrease) of the respective resistance R₄.

The sensor 1 also comprises electrical connection means, comprising contact pads 50 and metal connection tracks (not shown here), which allow the electrical connection of the sensor 1, in particular of the transduction elements 46-49, to an electrical detection circuit for reading the resistances R₁-R₄.

FIG. 5 shows an embodiment of the detection circuit, here indicated by 50, wherein the piezoresistors 46-49 are electrically coupled to each other in a Wheatstone bridge configuration between a supply voltage V_{cc} and ground GND.

In particular, the piezoresistor 46 and the piezoresistor 47 form a half-bridge and are connected in series between the supply voltage V_{cc} and the ground GND. The piezoresistor 48 and the piezoresistor 49 form a half-bridge and are connected in series between the supply voltage V_{cc} and the ground GND.

An operational amplifier 52 is coupled to the piezoresistors 46-49 and provides a voltage Vout.

In use, in presence of the external pressure Pext to be measured, the pressure P₂ of the first chamber 12 and the buried cavity 30 is equal to the external pressure Pext.

Consequently, between the upper surface 25B and the lower surface 25A of the membrane 25 a pressure difference Pext−P₁ is present, and between the upper surface 32B and the lower surface 32A of the membrane 32 a pressure difference P₁−Pext is present.

In practice, the membranes 25, 32 are subject, in use, to a pressure difference being equal in magnitude but having opposite sign.

FIG. 6 shows an example where Pext=P²>P¹. In this case, the membrane 25 undergoes a downward deformation, while the membrane 32 undergoes an upward deformation.

The Wheatstone bridge configuration of the transduction elements 46-49 allows a differential detection of the pressure Pext to be obtained; therefore, any spurious-type mechanical stresses that may affect the first and the second detection structures 18, 19 may be canceled as common mode. Consequently, the sensor 1 may have a high rejection of also internal undesired mechanical stimuli. Furthermore, both membranes 25, 32 deform as a function of the external pressure Pext; consequently, both membranes 25, 32 contribute to the useful signal that allows the external pressure Pext to be measured. The sensor 1 may therefore have a high detection sensitivity.

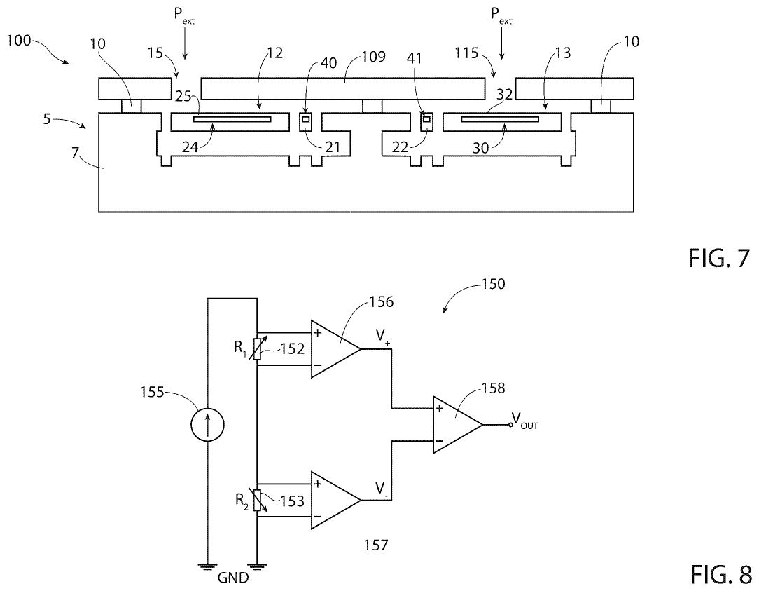

FIG. 7 shows a schematic cross-section of a MEMS pressure sensor 100, according to a different embodiment. The sensor 100 has a general structure similar to that of the sensor 1; consequently, common elements are indicated by the same reference numerals and are not further described in detail.

The sensor 100 comprises the body 5 having the lower substrate 7 and an upper substrate, here indicated by 109, mutually bonded through the bonding region 10.

The sensor 100 has the first and the second chambers 12, 13 wherein the first and, respectively, the second detection structure 18, 19 are accommodated.

Also in this embodiment, the first detection structure 18 is a structure suspended through the elastic element 21 and comprises the buried cavity 24 and the membrane 25; and the second detection structure 19 is a structure suspended through the elastic element 22 and comprises the buried cavity 30 and the membrane 32.

Also here, the first chamber 12 and the buried cavity 30 are fluidically coupled by the channel 40, and the second chamber 13 and the buried cavity 24 are fluidically coupled by the channel 41.

In this embodiment, the opening 15 is a first opening of the upper substrate 109 and the upper substrate 109 also comprises a second opening 115 on the second chamber 13.

Although not shown, transduction elements are coupled to the membranes 25, 32 for detecting the respective deformations, similarly to what has been discussed for the sensor 1.

In practice, in this embodiment, the sensor 100 may be used as a differential pressure sensor between two external pressures Pext, Pext′.

In fact, here, the first chamber 12 and the buried cavity 30 are at the pressure Pext, and the second chamber 13 and the buried cavity 24 are at the pressure Pext′.

Finally, it is clear that modifications and variations may be made to the sensors 1, 100 described and illustrated herein without thereby departing from the scope of the present disclosure, as defined in the attached claims.

For example, the openings 15, 115 may be formed (one or both) through the lower substrate 7 and not through the upper substrate 9, 109.

For example, the detection structures 18, 19, the membranes 25, 32 and the elastic elements 21, 22 may have a different shape from what has been shown, depending on the specific application.

The membranes 25, 32 may have, in-plan, a non-square shape, for example

rectangular or of other type, for example regular or non-regular, such as a polygon having a different number of sides or they may have a substantially circular shape.

For example, the membranes 25, 32 may be deformable elements configured to deform as a function of a pressure difference, of a different type and shape from a membrane, for example cantilevers or other.

For example, the detection structures 18, 19 may be structures that are non-suspended and integral with the body 5, in particular with the lower substrate 7.

For example, the pressure sensor may comprise one or more getter layers arranged on one or more walls of one or more of the chambers 12, 13 and the buried cavities 25, 32. In particular, with reference to the absolute pressure sensor described with reference to FIG. 1, a getter layer may be arranged on the (lower) internal wall of the upper substrate 9 which faces the second chamber 13, so that the pressure P₁ is as low as possible.

For example, the transduction elements 46-49 may be based on a different transduction principle, for example piezoelectric, capacitive, etc., to detect the deformation of the membranes 25, 32.

The present pressure sensor may have a different number of transduction elements, for example one for each of the membranes 25, 32, and/or the transduction elements may be coupled to each other according to circuit configurations.

For example, FIG. 8 shows a different embodiment of the detection circuit, here indicated by 150, which may be used in case the present sensor has only one transduction element 152 coupled to the membrane 25 and only one transduction element 153 coupled to the membrane 32.

The transduction elements 152, 153 are piezoresistors having resistance R₁ and, respectively, R₂.

The piezoresistors 152, 153 are sensitive to the direction along the third axis Z of the deformation of the respective membrane 25, 32. In particular, the piezoresistors 152, 153 are configured so that the respective resistance R₁, R₂ undergoes a positive (or, alternatively, a negative) variation in response to an upward deformation of the respective membrane 25, 32 and a negative (or, alternatively, a positive) variation in response to a downward deformation of the respective membrane 25, 32.

The detection circuit 150 is an Anderson loop wherein the piezoresistors 152, 153 are arranged in series with each other.

In detail, the detection circuit 150 comprises a current generator 155 which provides a reading current to the piezoresistors 152, 153; an operational amplifier 156 coupled at input to the piezoresistor 152; an operational amplifier 157 coupled at input to the piezoresistor 153; and an operational amplifier 158 coupled to the outputs of the operational amplifiers 156, 157 and providing the voltage Vout. In practice, the operational amplifier 158 operates as a subtractor that cancels any common mode stress components that affect the variation of the resistances R₁, R₂.

In this manner, the output voltage Vout is only a function of the external pressure to be measured and, at least as a first approximation, independent of spurious mechanical stresses.

The electrical detection circuits 50, 150 may be integrated in the same die wherein the sensor is integrated, or in a separate die, depending on the specific application.

The electrical connections among the transduction elements may be formed in the die wherein the transduction elements are formed, or in the die wherein the detection circuit is formed.

Finally, the different embodiments described above may be combined to provide further solutions.

A pressure sensor (1; 100) is summarized as including: a body (5) having a first chamber (12) and a second chamber (13) hermetically separated from the first chamber; a first detection structure (18) arranged in the first chamber (12), including a first deformable element (25) and a first buried cavity (24) within the first detection structure, wherein the first deformable element is configured to undergo a deformation as a function of a pressure difference between the first chamber and the first buried cavity; a second detection structure (19) arranged in the second chamber (13), including a second deformable element (32) and a second buried cavity (30) within the second detection structure, wherein the second deformable element is configured to undergo a deformation as a function of a pressure difference between the second chamber and the second buried cavity; a first channel (40, 43) extending into the body (5) and configured to fluidically couple the first buried cavity (24) with the second chamber (13); and a second channel (41, 44) extending into the body (5) and configured to fluidically couple the second buried cavity (30) with the first chamber (12).

The first deformable element (25) has a first face (25A) facing the first buried cavity (24) and a second face (25B) opposite to the first face and facing the first chamber (12), and the second deformable element (32) has a first face (32A) facing the second buried cavity (30) and a second face (32B) opposite to the first face and facing the second chamber (13).

The first detection structure (18) is a structure suspended in the first chamber (12) and/or the second detection structure (19) is a structure suspended in the second chamber (13).

The pressure sensor may include at least one opening (15; 115) that extends through the body (5) and is configured to couple one of the first and the second chambers with an external pressure (Pext, Pext′).

The at least one opening is a first opening (15) configured to fluidically couple the first chamber (12) with the external pressure (Pext), the sensor further includes a second opening (115) extending through the body (5) and configured to fluidically couple the second chamber (13) with a second external pressure (Pext′).

The body (5) includes a lower substrate (7), an upper substrate (9; 109) and a bonding region (10) configured to hermetically couple the upper substrate with the lower substrate.

The pressure sensor further includes at least one first transduction element (46, 47; 152) configured to detect the deformation of the first deformable element (25), and at least one second transduction element (48, 49; 153) configured to detect the deformation of the second deformable element (32).

The at least one first transduction element (46, 47; 152) is sensitive to the direction of the deformation of the first deformable element (25) and the at least one second transduction element (48, 49; 153) is sensitive to the direction of the deformation of the second deformable element (32).

The at least one first transduction element and/or the at least one second transduction element are piezoresistors.

The pressure sensor further includes a detection circuit (50; 150) configured to perform a differential reading of the deformation of the first deformable element (25) and the second deformable element (32).

The pressure sensor is of MEMS type.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A pressure sensor comprising:
a body having a first chamber and a second chamber hermetically separated from the first chamber;
a first detection structure arranged in the first chamber, the first detection structure including a first deformable element and a first buried cavity within the first detection structure, wherein the first deformable element is configured to, in operation, undergo a deformation as a function of a pressure difference between the first chamber and the first buried cavity;
a second detection structure arranged in the second chamber, the second detection structure including a second deformable element and a second buried cavity within the second detection structure, wherein the second deformable element is configured to, in operation, undergo a deformation as a function of a pressure difference between the second chamber and the second buried cavity;
a first channel extending into the body, the first channel fluidically couples the first buried cavity with the second chamber; and
a second channel extending into the body, the second channel fluidically couples the second buried cavity with the first chamber.

2. The pressure sensor according to claim 1, wherein the first deformable element has a first face facing the first buried cavity and a second face opposite to the first face and facing the first chamber, and wherein the second deformable element has a first face facing the second buried cavity and a second face opposite to the first face and facing the second chamber.

3. The pressure sensor according to claim 1, wherein the first detection structure is a structure suspended in the first chamber.

4. The pressure sensor according to claim 3, wherein the second detection structure is a structure suspended in the second chamber.

5. The pressure sensor according to claim 1, comprising at least one opening that extends through the body, the at least one opening couples one of the first chamber and the second chamber with an external pressure.

6. The pressure sensor according to claim 5, further comprising a second opening extending through the body and fluidically coupling the second chamber with a second external pressure, and wherein the at least one opening is a first opening fluidically coupling the first chamber with the external pressure.

7. The pressure sensor according to claim 1, wherein the body includes a lower substrate, an upper substrate, and a bonding region that hermetically couples the upper substrate with the lower substrate.

8. The pressure sensor according to claim 1, further comprising at least one first transduction element configured to, in operation, detect the deformation of the first deformable element, and at least one second transduction element configured to, in operation, detect the deformation of the second deformable element.

9. The pressure sensor according to claim 8, wherein the at least one first transduction element is sensitive to a direction of the deformation of the first deformable element and the at least one second transduction element is sensitive to a direction of the deformation of the second deformable element.

10. The pressure sensor according to claim 8, wherein the at least one first transduction element is a piezoresistor.

11. The pressure sensor according to claim 10, wherein the at least one second transduction element is a piezoresistor.

12. The pressure sensor according to claim 1, further comprising a detection circuit configured to, in operation, perform a differential reading of the deformation of the first deformable element and the deformation of the second deformable element.

13. A pressure sensor, comprising:
a first substrate including a surface;
a first chamber extending into the surface of the first substrate;
a second chamber extending into the surface of the first substrate;
a wall portion between the first chamber and the second chamber, the wall portion partially delimits the first chamber and partially delimit the second chamber;
a bonding region on the surface of the first substrate;
a second substrate coupled to the first substrate by the bonding region;
a first elastic element extends from the wall portion into the first chamber;
a second elastic element extends from the wall portion into the second chamber;
a first detection structure coupled to the first elastic element;
a second detection structure coupled to the second elastic element;
a first buried cavity within the first detection structure;
a first channel in fluid communication with the first buried cavity, extends through the first elastic element, and extends through the wall portion;
a first opening extends into the surface, is in fluid communication with the second chamber, and is fluidically coupled to the first channel;
a second buried cavity within the second detection structure;
a second channel in fluid communication with the second buried cavity, extends through the second elastic element, and extends through the wall portion; and
a second opening extends into the surface, is in fluid communication with the first chamber, and is fluidically coupled to the second channel.

14. The pressure sensor of claim 13, further comprising a third opening that extends through the second substrate and is fluidically coupled to the first chamber.

15. The pressure sensor of claim 14, further comprising a fourth opening that extends through the second substrate and is fluidically coupled to the second chamber.

16. The pressure sensor of claim 13, further comprising a third opening that extends through the first substrate and is fluidically coupled to the first chamber.

17. The pressure sensor of claim 14, further comprising a fourth opening that extends through the first substrate and is fluidically coupled to the second chamber.

18. A pressure sensor, comprising:
a first substrate including a surface, a first chamber that extends into the surface, and a wall portion that partially delimits the first chamber;
a first elastic element extends from the wall portion into the first chamber;
a first detection structure coupled to the first elastic element, the first detection structure is suspended within the first chamber by the first elastic element;
a first buried cavity within the first detection structure;
a first channel in fluid communication with the first buried cavity, the first channel extends through the first elastic element and extends through the wall portion; and
a first opening extends into the surface, the first opening is in fluid communication with the second chamber and is fluidically coupled to the first channel.

19. The pressure sensor of claim 18, wherein the first substrate includes a second chamber spaced apart from the first chamber by the wall portion, and the wall portion partially delimits the second chamber, and further comprising:
a second elastic element that extends form the wall portion into the second chamber;
a second detection structure coupled to the second elastic element, the second detection structure is suspended within the second chamber by the second elastic element;
a second buried cavity within the second detection structure;
a second channel in fluid communication with the second buried cavity, the second channel extends through the second elastic element and extends through the wall portion;
a second opening extends into the surface, the second opening.

20. The pressure sensor of claim 19, further comprising:
a bonding region on the surface of the first substrate and overlapping the wall portion; and
a second substrate coupled to the first substrate by the bonding region.
